(19) United States
(12) Patent Application Publication
(10) Pub. No.: US 2025/0105220 A1
(43) Pub. Date: Mar. 27, 2025

(54) VERTICALLY STACKED LIGHT-EMITTING DIODE STRUCTURE

(71) Applicant: RAYLEIGH VISION LIMITED, Kowloon (HK)

(72) Inventors: Jr-Hau He, Hsinchu City (TW); Zhi-Ting Ye, Miaoli County (TW); Chun-Wei Tsai, New Taipei City (TW); Der-Hsien Lien, Taipei (TW); Yuk-Tong Cheng, Kowloon (HK)

(21) Appl. No.: 18/373,488

(22) Filed: Sep. 27, 2023

(51) Int. Cl. H01L 25/075; H01L 33/60; H01L 33/62

(52) U.S. Cl. CPC H01L 25/0756; H10H 20/856; H10H 20/857

(57) ABSTRACT

The present invention provides a vertically stacked light-emitting diode (LED) structure, which comprises a substrate, a first light-emitting device, a first reflection layer, a second light-emitting device, a second reflection layer, and a third light-emitting device. The layers are stacked sequentially. The first light-emitting device, the second light-emitting device, and the third light-emitting device are connected electrically to the pads located on the edges of the substrate. In addition, the first reflection layer and the second reflection layer are used to reflect and filter the light from the first light-emitting device, the second light-emitting device, and the third light-emitting device. By using this structure, the area of the light-emitting diode structure can be further shrunk.

### BACKGROUND OF THE INVENTION

Micro light-emitting diode (LED) is an emerging display technology, which is composed of smaller light-emitting chips. Compared with existing LEDs or organic light-emitting diode (OLED) display technologies, micro LEDs have higher brightness, contrast, and color expression, as well as higher energy efficiency and longer life.

Micro LEDs offer many advantages over existing display technologies. The first is brightness and contrast. The brightness of micro LEDs can be more than 10 times that of ordinary OLEDs, and the contrast ratio is also high. This enables micro LED displays to significantly improve color reproduction and image quality.

The advantage of micro LEDs is color expression. Because micro LED displays use a pure light source, they can display a wider color gamut, providing truer, more vivid colors. At the same time, micro LED displays can also achieve local dimming, which means that it can achieve independent brightness adjustment in different areas on the same screen, thereby achieving better contrast and energy efficiency.

The third advantage is energy efficiency and longer life. Micro LEDs uses a pure light source, so there is no need for a backlight and a color filter layer, and thus improving light extraction efficiency.

Due to the advantages of micro LEDs, it has become the technology of choice for many high-end display products, including smartphones, tablets, TVs, VR/AR headsets, and automotive displays.

As consumer demand for higher-quality and higher-resolution displays continues to increase, micro LED technology is beginning to receive more attention. Compared with traditional LCD displays, LED displays and OLED displays, micro LED displays have higher brightness, better contrast, and a wider color space, so they are regarded as the next generation and important development direction of display technology.

The advantages of micro LEDs are also reflected in reliability and long-term cost of use. Due to their long life and high durability, micro LEDs are more cost-effective compared to other technologies. Because micro LEDs have low power consumption and long life, this technology can maintain high-quality displays over a long period of time without requiring excessive maintenance or replacement parts.

However, the micro LED system according to the prior art has red, green, and blue LED arranged horizontally, making it difficult to further reduce the overall area. When one of them is damaged, it is difficult to replace and repair due to its horizontal structure. Therefore, as electronic products are gradually miniaturized, the industry needs a LED structure that can effectively reduce the light-emitting area and is easy to replace and repair.

To solve the above problems in the prior art, the present invention provides a vertically stacked LED structure. A plurality of light-emitting devices are stacked on a substrate. One electrode of each of the plurality of light-emitting devices extend to a plurality of pads on the substrate, respectively, for shrinking the area of the LED structure. In addition, when one or a plurality of the LEDs is damaged, the corresponding substrate can be removed for replacing the whole of the vertically stacked LED structure directly.

### SUMMARY OF THE INVENTION

An objective of the present invention is to provide a vertically stacked LED structure. A plurality of light-emitting devices are stacked on a substrate. One electrode of each of the plurality of light-emitting devices extends to a plurality of pads of the substrate, respectively. The other electrode of each of the plurality of light-emitting devices is connected to common pad. By using this structure, LEDs with smaller area can be provided. In addition, when one or a plurality of the LEDs is damaged, the corresponding substrate can be removed for replacing the whole of the vertically stacked LED structure directly and repairing the micro LED panel rapidly.

To achieve the above objective and efficacy, the present invention provides a vertically stacked LED structure, which comprises a substrate, a first light-emitting device, a first reflection layer, a second light-emitting device, a second reflection layer, and a third light-emitting device. A first pad, a second pad, a third pad, and a common pad are disposed on the substrate separately. A first bump, a second bump, a third bump, and a common bump are disposed below the substrate separately. The first pad is connected electrically to the first bump; the second pad is connected electrically to the second bump; the third pad is connected electrically to the third bump; and the common pad is connected electrically to the common bump. The first light-emitting device is disposed on the substrate. The first light-emitting device is connected electrically to the common pad via a common electrode at the bottom. The first light-emitting device is connected electrically to the first pad via a first electrode on the first light-emitting device. The first reflection layer is disposed on the first light-emitting device. The second light-emitting device is disposed on the first reflection layer. The second light-emitting device is connected electrically to the common electrode from the bottom. The second light-emitting device is connected electrically to the second pad via a second electrode on the second light-emitting device. The second reflection layer is disposed on the second light-emitting device. The third light-emitting device is disposed on the second reflection layer. The third light-emitting device is connected electrically to the common electrode from the bottom. The third light-emitting device is connected electrically to the third pad via a third electrode on the third light-emitting device. A first area of the first light-emitting device is greater than a second area of the second light-emitting device. The second area of the second light-emitting device is greater than a third area of the third light-emitting device. This structure provides LEDs with smaller area and the structure can be replaced and repaired as a whole.

To achieve the above objective and efficacy, the present invention provides a vertically stacked LED structure, which comprises a substrate, a first light-emitting device, a first reflection layer, a second light-emitting device, a second reflection layer, and a third light-emitting device. A first pad, a second pad, a third pad, and a common pad are disposed on the substrate separately. A first bump, a second bump, a third bump, and a common bump are disposed below the substrate separately. The first pad is connected electrically to the first bump; the second pad is connected electrically to the second bump; the third pad is connected electrically to the third bump; and the common pad is connected electrically to the common bump. The first light-emitting device is disposed on the substrate. The first light-emitting device is connected electrically to the common pad via a common electrode at the bottom. The first light-emitting device is connected electrically to the first pad via a first electrode on the first light-emitting device. The first reflection layer is disposed on the first light-emitting device. The second light-emitting device is disposed on the first reflection layer. The second light-emitting device is connected electrically to the common electrode from the bottom. The second light-emitting device is connected electrically to the second pad via a second electrode on the second light-emitting device. The second reflection layer is disposed on the second light-emitting device. The third light-emitting device is disposed on the second reflection layer. The third light-emitting device is connected electrically to the common electrode from the bottom. The third light-emitting device is connected electrically to the third pad via a third electrode on the third light-emitting device. A first area of the first light-emitting device is smaller than a second area of the second light-emitting device. The second area of the second light-emitting device is smaller than a third area of the third light-emitting device. This structure provides LEDs with smaller area and the structure can be replaced and repaired as a whole.

According to an embodiment of the present invention, the first pad, the second pad, the third, and the common pad are disposed on the edges of the substrate, respectively.

According to an embodiment of the present invention, said first light-emitting device, said second light-emitting device and said third light-emitting device emits red, green, or blue light.

According to an embodiment of the present invention, said second area is 75% of said first area, and said third area is 50% of said first area.

According to an embodiment of the present invention, said second area is 125% of said first area, and said third area is 150% of said first area.

According to an embodiment of the present invention, further comprising a first transparent glue layer and a second transparent glue layer. said first transparent glue layer disposed between said first reflection layer and said second light-emitting device; said second transparent glue layer disposed between said second reflection layer and said third light-emitting.

### BRIEF DESCRIPTION OF DRAWINGS

FIG. 1 shows a stereoscopic view of the structure according to the first embodiment of the present invention;

FIG. 2 shows a schematic diagram of the structure according to the first embodiment of the present invention;

FIG. 3 shows a top view of the structure according to the first embodiment of the present invention;

FIG. 4 shows a stereoscopic view of the structure according to the second embodiment of the present invention;

FIG. 5 shows a schematic diagram of the structure according to the second embodiment of the present invention; and

FIG. 6 shows a top view of the structure according to the second embodiment of the present invention.

### DETAILED DESCRIPTION OF THE INVENTION

In order to make the structure and characteristics as well as the effectiveness of the present invention to be further understood and recognized, the detailed description of the present invention is provided as follows along with embodiments and accompanying figures.

To solve the problems according to the prior art as described above, the present invention provides a vertically stacked LED structure, which comprises a substrate, a first light-emitting device, a first reflection layer, a second light-emitting device, a second reflection layer, and a third light-emitting device stacked sequentially. The first light-emitting device, the second light-emitting device, and the third light-emitting device are connected electrically to the pads located on the edges of the substrate. In addition, the first reflection layer and the second reflection layer are used to reflect and filter the light from the first light-emitting device, the second light-emitting device, and the third light-emitting device. By using this stacked structure, the area of the light-emitting diode structure can be further shrunk. Thereby, the problems of area and difficulty in replacement and repair for the micro LED according to the prior art can be solved.

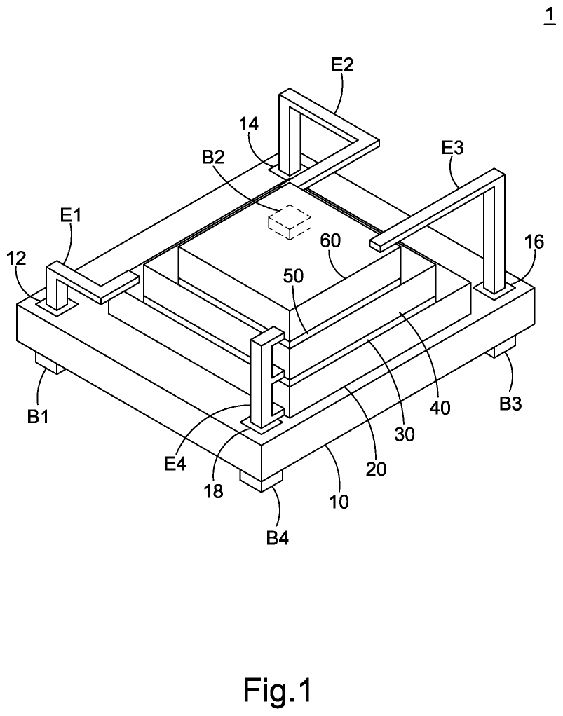

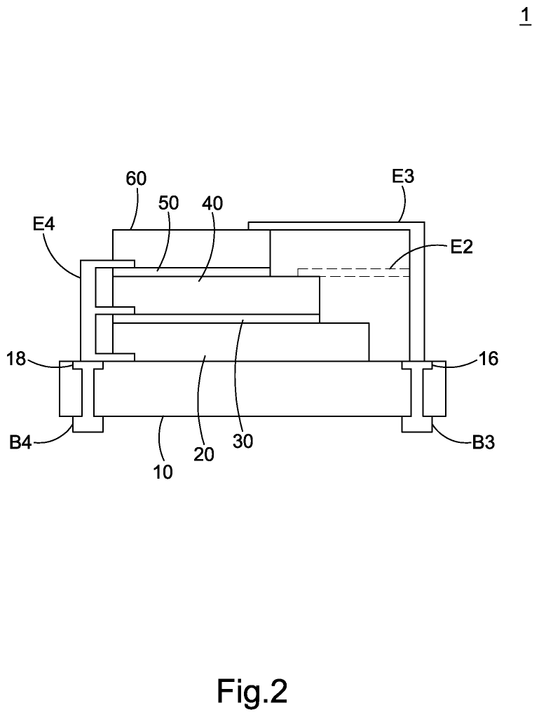

Please refer to FIG. 1 and FIG. 2. FIG. 1 shows a stereoscopic view of the structure according to the first embodiment of the present invention; FIG. 2 shows a schematic diagram of the structure according to the first embodiment of the present invention. As shown in the figures, the first embodiment provides a vertically stacked LED structure 1, which comprises a substrate 10, a first light-emitting device 20, a first reflection layer 30, a second light-emitting device 40, a second reflection layer 50, and a third light-emitting device 60. These components are stacked.

Please refer again to FIG. 1 and FIG. 2. As shown in the figures, according to the present embodiment, a first pad 12, a second pad 14, a third pad 16, and a common pad 18 are disposed on the substrate 10 separately. A first bump B1, a second bump B2, a third bump B3, and a common bump B4 are disposed below the substrate 10 separately. The first pad 12 is connected electrically to the first bump B1; the second pad 14 is connected electrically to the second bump B2; the third pad 16 is connected electrically to the third bump B3; and the common pad 18 is connected electrically to the common bump B4. According to the present embodiment, the plurality of pads are connected electrically to the plurality of bumps via the inside of the substrate 10. The first light-emitting device 20 is disposed on the substrate 10. The first light-emitting device 20 is connected electrically to the common pad 18 via a common electrode E4 at the bottom. The first light-emitting device 20 is connected electrically to the first pad 12 via a first electrode E1 on the first light-emitting device 20. The first reflection layer 30 is disposed on the first light-emitting device 20. The second light-emitting device 40 is disposed on the first reflection layer 30. The second light-emitting device 40 is connected electrically to the common electrode E4 from the bottom. The second light-emitting device 40 is connected electrically to the second pad 14 via a second electrode E2 on the second light-emitting device 40. The second reflection layer 50 is disposed on the second light-emitting device 40. The third light-emitting device 60 is disposed on the second reflection layer 50. The third light-emitting device 60 is connected electrically to the common electrode E4 from the bottom. The third light-emitting device 60 is connected electrically to the third pad 16 via a third electrode E3 on the third light-emitting device 60.

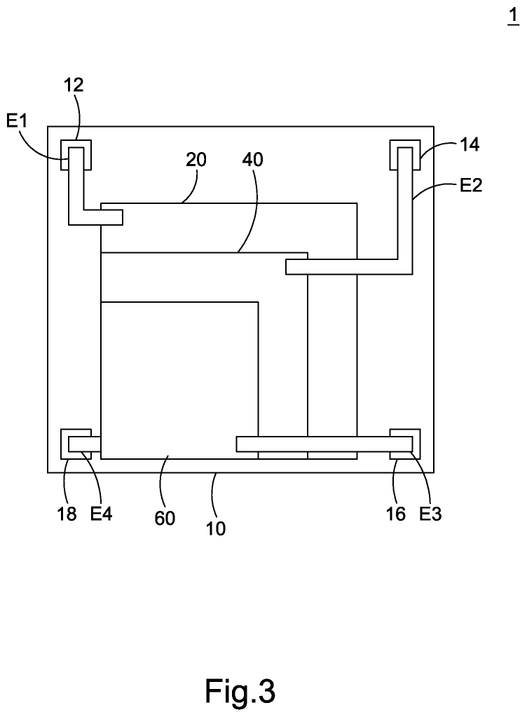

Please refer to FIG. 1 and FIG. 2 again and to FIG. 3, which shows a top view of the structure according to the first embodiment of the present invention. As shown in the figure, according to the present embodiment, the light-emitting surface of the first light-emitting device 20 includes a first area; the light-emitting surface of the second light-emitting device 40 includes a second area; and the light-emitting surface of the third light-emitting device 60 includes a third area. According to the present embodiment, the first area is greater than the second area; and the second area is greater than the third area. Thereby, the first light-emitting device 20, the second light-emitting device 40, and the third light-emitting device 60 form a structure with areas shrinking from the bottom to the top. By vertically stacking a light-emitting device with a smaller area on one with a larger area, the light emitted from below will not be blocked by the light-emitting device above.

According to the present embodiment, the substrate 10 is a rectangular plate structure. The first pad 12, the second pad 14, the third pad 16, and the common pad 18 are disposed at the four corners of the substrate 10, respectively, and located on the edges of the substrate 10 such that the first light-emitting device 20 is surrounded by the first pad 12, the second pad 14, the third pad 16, and the common pad 18.

According to the present embodiment, the first bump B1, the second bump B2, the third bump B3, and the common bump B4 below the substrate 10 can be further connected electrically to another substrate. For example, the substrate 10 can be disposed on, but not limited to, the control circuit board of a display.

According to the present embodiment, the wavelength of the first light-emitting device 20 is different from the wavelength of the second light-emitting device 40; the wavelength of the second light-emitting device 40 is different from the wavelength of the third light-emitting device 60; and the wavelength of the first light-emitting device 20 is different from the wavelength of the third light-emitting device 60. For example, the first light-emitting 20, the second light-emitting device 40, and the third light-emitting device 60 emit light with different colors. Nonetheless, the present invention is not limited to the present embodiment.

According to the present embodiment, the first light-emitting device 20 emits, but not limited to, red, green, or blue light.

According to the present embodiment, the second light-emitting device 40 emits, but not limited to, red, green, or blue light.

According to the present embodiment, the third light-emitting device 60 emits, but not limited to, red, green, or blue light.

According to the present embodiment, the first light-emitting 20, the second light-emitting device 40, and the third light-emitting device 60 include an n-type semiconductor layer, a p-type semiconductor layers, and a light-emitting layer (not shown in the figures), respectively. According to the present embodiment, the n-type semiconductor layer of the first light-emitting device 20 is connected electrically to the common electrode E4. The p-type semiconductor layer of the first light-emitting device 20 is connected electrically to the first electrode E1. The n-type semiconductor layer of the second light-emitting device 40 is connected electrically to the common electrode E4. The p-type semiconductor layer of the second light-emitting device 40 is connected electrically to the second electrode E2. The n-type semiconductor layer of the third light-emitting device 60 is connected electrically to the common electrode E4. The p-type semiconductor layer of the third light-emitting device 60 is connected electrically to the third electrode E3. By using the light-emitting device structure with vertical electrodes, the area of the vertically stacked LED structure 1 can be further shrunk.

According to the present embodiment, the first light-emitting 20, the second light-emitting device 40, and the third light-emitting device 60 are light-emitting diodes. The semiconductor materials will be first doped to generate the p-type and n-type structures. Like other diodes, the current in an LED can flow from the p-electrode (the anode) to the n-electrode (the cathode) easily and cannot flow in the reverse direction. The two carriers, holes and electrons, flow between the electrode and the p- or n-type structure under different bias conditions. When holes and electrons encounter and recombine, electrons will fall to lower energy levels and emit energy in the form of photons (light). The first light-emitting 20, the second light-emitting device 40, and the third light-emitting device 60 can adopt micro LEDs, which are LEDs with size smaller than micrometers. Nonetheless, the present invention is not limited to the present embodiment.

According to the present embodiment, when one or a plurality of the first light-emitting 20, the second light-emitting device 40, and the third light-emitting device 60 is damaged, the substrate 10 can be removed correspondingly for replacing the vertically stacked LED structure 1.

According to the present embodiment, the first light-emitting 20, the first reflection layer 30, the second light-emitting device 40, the second reflection layer 50, and the third light-emitting device 60 are transparent layers, allowing the light emitted from the first light-emitting 20, the second light-emitting device 40, and the third light-emitting device 60 to pass through.

According to the present embodiment, the first reflection layer 30 is a narrow bandpass thin film. It allows the light from the first light-emitting device 20 to pass through. In addition, the first reflection layer 30 reflects the light from the second light-emitting device 40 and the third light-emitting device 60 for enhancing the light-emitting efficiency of the first light-emitting 20, the second light-emitting device 40, and the third light-emitting device 60.

According to the present embodiment, the second reflection layer 50 is a narrow bandpass thin film. It allows the light from the first light-emitting device 20 and the second light-emitting device 40 to pass through. In addition, the second reflection layer 50 reflects the light from the third light-emitting device 60 for enhancing the light-emitting efficiency of the first light-emitting 20, the second light-emitting device 40, and the third light-emitting device 60.

According to the present embodiment, furthermore, the first reflection layer 30 and the second reflection layer 50 are insulative materials. The first reflection layer 30 blocks the first light-emitting device 20 and the second light-emitting device 40. The second reflection layer 50 blocks the second light-emitting device 40 and the third light-emitting device 60.

According to an embodiment, the material of the substrate 10 is selected from one of gallium nitride, gallium arsenide, gallium phosphide, indium phosphide, and aluminum oxide. Nonetheless, the present invention is not limited to the embodiment.

According to an embodiment, the material of the first light-emitting device 20, the second light-emitting device 40, and the third light-emitting device 60 is selected from one of gallium nitride, aluminum indium phosphide, aluminum gallium arsenide, and aluminum gallium phosphide. Nonetheless, the present invention is not limited to the embodiment.

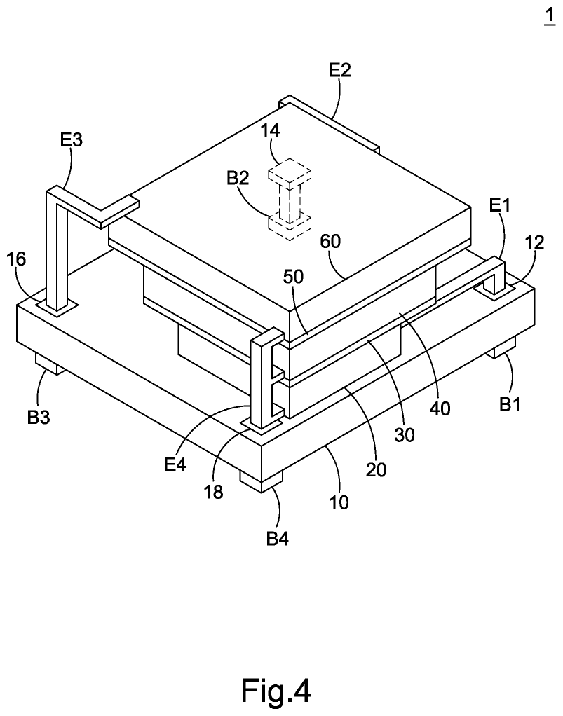

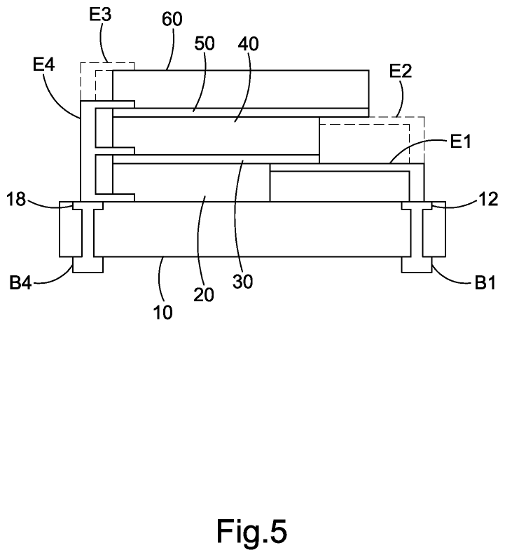

Please refer to FIG. 4 and FIG. 5. FIG. 4 shows a stereoscopic view of the structure according to the second embodiment of the present invention; FIG. 5 shows a schematic diagram of the structure according to the second embodiment of the present invention. As shown in the figures, the first embodiment provides a vertically stacked LED structure 1, which comprises a substrate 10, a first light-emitting device 20, a first reflection layer 30, a second light-emitting device 40, a second reflection layer 50, and a third light-emitting device 60. These components are stacked.

Please refer again to FIG. 4 and FIG. 5. As shown in the figures, according to the present embodiment, a first pad 12, a second pad 14, a third pad 16, and a common pad 18 are disposed on the substrate 10 separately. A first bump B1, a second bump B2, a third bump B3, and a common bump B4 are disposed below the substrate 10 separately. The first pad 12 is connected electrically to the first bump B1; the second pad 14 is connected electrically to the second bump B2; the third pad 16 is connected electrically to the third bump B3; and the common pad 18 is connected electrically to the common bump B4. According to the present embodiment, the plurality of pads are connected electrically to the plurality of bumps via the inside of the substrate 10. The first light-emitting device 20 is disposed on the substrate 10. The first light-emitting device 20 is connected electrically to the common pad 18 via a common electrode E4 at the bottom. The first light-emitting device 20 is connected electrically to the first pad 12 via a first electrode E1 on the first light-emitting device 20. The first reflection layer 30 is disposed on the first light-emitting device 20. The second light-emitting device 40 is disposed on the first reflection layer 30. The second light-emitting device 40 is connected electrically to the common electrode E4 from the bottom. The second light-emitting device 40 is connected electrically to the second pad 14 via a second electrode E2 on the second light-emitting device 40. The second reflection layer 50 is disposed on the second light-emitting device 40. The third light-emitting device 60 is disposed on the second reflection layer 50. The third light-emitting device 60 is connected electrically to the common electrode E4 from the bottom. The third light-emitting device 60 is connected electrically to the third pad 16 via a third electrode E3 on the third light-emitting device 60.

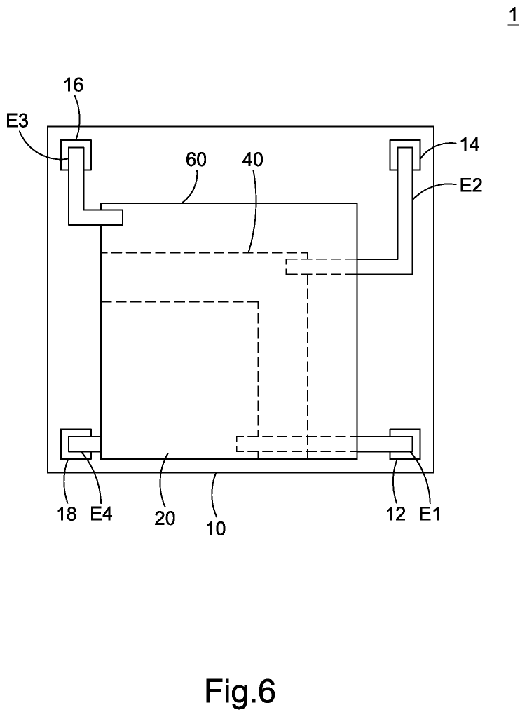

Please refer to FIG. 4 and FIG. 5 again and to FIG. 6, which shows a top view of the structure according to the second embodiment of the present invention. As shown in the figure, according to the present embodiment, the light-emitting surface of the first light-emitting device 20 includes a first area; the light-emitting surface of the second light-emitting device 40 includes a second area; and the light-emitting surface of the third light-emitting device 60 includes a third area. According to the present embodiment, the first area is smaller than the second area; and the second area is smaller than the third area. Thereby, the first light-emitting device 20, the second light-emitting device 40, and the third light-emitting device 60 form a structure with areas increasing from the bottom to the top. While stacking vertically, the light-emitting device with stronger light intensity can be disposed at the bottom and one with lower light intensity can be disposed on the top for adjusting the overall emitted light from the light-emitting devices. The relation among the other components according to the present embodiment is identical to the above embodiment. Hence, the details will not be repeated.

According to an embodiment, further comprising a first transparent glue layer (not shown in the figures) and a second transparent glue layer (not shown in the figures). the first transparent glue layer disposed between the first reflection layer 30 and the second light-emitting device 40; the second transparent glue layer disposed between the second reflection layer 50 and the third light-emitting 60.

To sum up, the present invention provides a vertically stacked LED structure. A plurality of light-emitting devices are stacked on a substrate. One electrode of each of the plurality of light-emitting devices extends to a plurality of pads of the substrate, respectively. The other electrode of each of the plurality of light-emitting devices is connected to common pad for shrinking the overall light-emitting area. In addition, when one or a plurality of the LEDs is damaged, the corresponding substrate can be removed for replacing the whole of the vertically stacked LED structure directly and repairing the micro LED panel rapidly. Thereby, the problems of area and difficulty in replacement and repair for the micro LED according to the prior art can be solved.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A vertically stacked light-emitting diode structure, comprising:
a substrate, including a first pad, a second pad, a third pad, and a common pad disposed thereon separately, including a first bump, a second bump, a third bump, and a common bump disposed therebelow substrate separately, said first pad connected electrically to said first bump, said second pad connected electrically to said second bump, said third pad connected electrically to said third bump, and said common pad connected electrically to said common bump;
a first light-emitting device, disposed on said substrate, connected electrically to said common pad via a common electrode at the bottom, and connected electrically to said first pad via a first electrode thereon;
a first reflection layer, disposed on said first light-emitting device;
a second light-emitting device, disposed on said first reflection layer, connected electrically to said common electrode from the bottom, and connected electrically to said second pad via a second electrode thereon;
a second reflection layer, disposed on said second light-emitting device; and
a third light-emitting device, disposed on said second reflection layer, connected electrically to said common electrode from the bottom, and connected electrically to said third pad via a third electrode thereon;
wherein a first area of said first light-emitting device is greater than a second area of said second light-emitting device; and said second area of said second light-emitting device is greater than a third area of said third light-emitting device.

2. The vertically stacked light-emitting diode structure of claim 1, wherein said first pad, said second pad, said third pad, and said common pad are disposed on said substrate, respectively, and located on the edges of said substrate.

3. The vertically stacked light-emitting diode structure of claim 1, wherein said first light-emitting device, said second light-emitting device and said third light-emitting device emits red, green, or blue light.

4. The vertically stacked light-emitting diode structure of claim 1, wherein said second area is 75% of said first area, and said third area is 50% of said first area.

5. The vertically stacked light-emitting diode structure of claim 1, further comprising a first transparent glue layer and a second transparent glue layer. said first transparent glue layer disposed between said first reflection layer and said second light-emitting device; said second transparent glue layer disposed between said second reflection layer and said third light-emitting.

6. A vertically stacked light-emitting diode structure, comprising:
a substrate, including a first pad, a second pad, a third pad, and a common pad disposed thereon separately, including a first bump, a second bump, a third bump, and a common bump disposed therebelow substrate separately, said first pad connected electrically to said first bump, said second pad connected electrically to said second bump, said third pad connected electrically to said third bump, and said common pad connected electrically to said common bump;
a first light-emitting device, disposed on said substrate, connected electrically to said common pad via a common electrode at the bottom, and connected electrically to said first pad via a first electrode thereon;
a first reflection layer, disposed on said first light-emitting device;
a second light-emitting device, disposed on said first reflection layer, connected electrically to said common electrode from the bottom, and connected electrically to said second pad via a second electrode thereon;
a second reflection layer, disposed on said second light-emitting device; and
a third light-emitting device, disposed on said second reflection layer, connected electrically to said common electrode from the bottom, and connected electrically to said third pad via a third electrode thereon;
wherein a first area of said first light-emitting device is smaller than a second area of said second light-emitting device; and said second area of said second light-emitting device is smaller than a third area of said third light-emitting device.

7. The vertically stacked light-emitting diode structure of claim 6, wherein said first pad, said second pad, said third pad, and said common pad are disposed on said substrate, respectively, and located on the edges of said substrate.

8. The vertically stacked light-emitting diode structure of claim 6, wherein said first light-emitting device, said second light-emitting device and said third light-emitting device emits red, green, or blue light.

9. The vertically stacked light-emitting diode structure of claim 6, wherein said second area is 125% of said first area, and said third area is 150% of said first area.

10. The vertically stacked light-emitting diode structure of claim 6, further comprising a first transparent glue layer and a second transparent glue layer. said first transparent glue layer disposed between said first reflection layer and said second light-emitting device; said second transparent glue layer disposed between said second reflection layer and said third light-emitting.
